(19) United States
(12) Patent Application Publication
(10) Pub. No.: US 2026/0096483 A1
(43) Pub. Date: Apr. 2, 2026

(54) Scalable Capacity and Bandwidth Expansion for Memory Systems

(71) Applicant: Apple Inc., Cupertino, CA (US)

(72) Inventor: Sanjay Dabral, Cupertino, CA (US)

(21) Appl. No.: 19/089,766

(22) Filed: Mar. 25, 2025

Related U.S. Application Data
(60) Provisional application No. 63/700,347, filed on Sep. 27, 2024.

(51) Int. Cl. H01L 25/065

(52) U.S. Cl. CPC H10W 90/00

(57) ABSTRACT

Memory system and methods of fabrication are described in which memory capacity and/or bandwidth can be expanded. In some implementations expansion may be accomplished with inclusion of custom buffer base dies, or other suitable components including network routing connecting multiple memory die stacks. In some implementations expansion may be accomplished with integration of vertically oriented memory die stacks.

### RELATED APPLICATIONS

This application claims the benefit of priority of U.S. Provisional Application No. 63/700,347, filed Sep. 27, 2024, which is incorporated herein by reference.

### BACKGROUND

### Field

Embodiments described herein relate to memory systems, and more particularly to high bandwidth memory systems.

### Background Information

Memory storage is an integral part of electronic devices such as personal computers, servers, gaming consoles, and mobile devices. Memory storage can be a particularly important component in high performance computing (HPC) and highly niche workloads such as artificial intelligence, analytics, edge computing, etc. that require high bandwidths and high speed data access. While double data rate (DDR) memory solutions are able to meet most practical needs, the more recent introduction of high bandwidth memory (HBM) provides a memory platform that can achieve higher bandwidth while using less power and a substantially smaller form factor than DDR. This is achieved by vertical stacking of multiple dynamic random access memory (DRAM) dies and onto a logic die that commonly includes buffer circuitry and test logic, and is also commonly referred to as a buffer die. HBM has a wider memory bus than DDR with a larger number of channels driven at lower data rates, which can translate to lower energy consumption compared to DDR. HBM also comes at a significant cost compared to DDR due to inclusion of an interposer used to accommodate the larger number of channels and fine wiring density.

### SUMMARY

Memory systems, and in particular HBM systems, and methods of assembly are described. In an embodiment a memory system includes a routing substrate, a processor on a first side of the routing substrate, a buffer base die on the first side of the routing substrate, a first memory die stack on the buffer base die, and a second memory die stack on the buffer base die. In accordance with embodiments, the buffer base die may include channel routing connected to both the first memory die stack and the second memory die stack.

In an embedment, a memory system includes a processor and a memory die stack operably coupled with the processor, where the memory die stack includes a bonding surface and a plurality of memory dies oriented orthogonal to the bonding surface.

### BRIEF DESCRIPTION OF THE DRAWINGS

FIG. 1A is a schematic cross-sectional side view illustration of a conventional HBM system.

FIG. 1B is a schematic top layout view illustration of a conventional HBM system.

FIG. 2 is a schematic cross-sectional side view illustration of a memory system with active buffer base die in accordance with an embodiment.

FIG. 3 is a schematic cross-sectional side view illustration of a memory system with active routing substrate in accordance with an embodiment.

FIG. 4 is a schematic top layout view illustration of a memory system including a row of memory die stacks on a buffer base die or passive interposer in accordance with an embodiment.

FIG. 5 is a schematic top layout view illustration of a memory system including rows and columns memory die stacks on a buffer base die or passive interposer in accordance with an embodiment.

FIG. 6 is a schematic top layout view illustration of a memory system including a row of memory die stacks on a buffer base die or passive interposer in accordance with an embodiment.

FIG. 7 is a schematic top layout view illustration of a memory system including rows and columns memory die stacks on a buffer base die or passive interposer in accordance with an embodiment.

FIGS. 8-9 are process flows for sequences of harvesting integrated buffer base dies or passive interposers in accordance with embodiments.

FIG. 10 is a schematic top layout view illustration of an active buffer base die with double sided PHY areas in accordance with an embodiment.

FIG. 11 is a schematic top layout view illustration of an active buffer base die with checkpoint features in accordance with an embodiment.

FIG. 12 is a schematic cross-sectional side view illustration of a memory system in which the processor PHY is relocated within an active interposer in accordance with an embodiment.

FIG. 13 is a schematic cross-sectional side view illustration of a memory system in which the processor PHY is relocated within an active routing substrate in accordance with an embodiment.

FIG. 14A is a schematic cross-sectional side view illustration of a memory system including an organic routing substrate and backside passive bridge die in accordance with an embodiment.

FIG. 14B is a schematic cross-sectional side view illustration of a memory system including an organic routing substrate and a backside active bridge die in accordance with an embodiment.

FIG. 14C is a schematic cross-sectional side view illustration of a memory system including an organic routing substrate and an embedded active bridge die in accordance with an embodiment.

FIG. 15 is a schematic top layout view of a memory system with passive local interconnect in accordance with embodiments.

FIGS. 16A-16B are schematic top layout view illustrations for memory systems with interchangeable memory or co-packaged optical engines in accordance with embodiments.

FIG. 16C is a schematic cross-sectional view taken along section C-C of FIG. 16B in accordance with an embodiment.

FIG. 17 is a schematic cross-sectional side view illustration of a memory system with an active buffer base die and horizontally aligned memory dies in accordance with an embodiment.

FIG. 18 is a schematic cross-sectional side view illustration of a memory system with an active buffer base die and vertically aligned memory dies in accordance with an embodiment.

FIG. 19 is a schematic top layout view illustration of a memory system including a plurality of memory die stacks with vertically aligned memory dies on a buffer base die in accordance with an embodiment.

FIG. 20 is a close-up schematic cross-sectional side view illustration of a memory die stack with vertically aligned memory dies on a buffer base die in accordance with an embodiment.

FIG. 21 is a schematic cross-sectional side view illustration for a memory system including a buffer base die designed to receive a plurality of die stacks with vertically oriented memory dies in accordance with an embodiment.

FIG. 22 is a schematic top view illustration of the plurality of areas of a buffer base die in accordance with an embodiment.

FIG. 23 is a schematic cross-sectional side view illustration of a memory package with folded die stack arrangement in accordance with an embodiment.

FIGS. 24A-24B are schematic bottom view illustrations of read/write contact pads for a memory die stack with vertically aligned memory dies in accordance with embodiments.

FIG. 25 is a schematic side view illustration of distributed activity within a memory die stack with vertically aligned memory dies in accordance with an embodiment.

FIG. 26 is a schematic side view illustration of a memory die stack with vertically aligned memory dies with thermal paths in accordance with an embodiment.

FIG. 27 is a schematic side view illustration of a memory die stack with vertically aligned memory dies and thermal shims in accordance with an embodiment.

FIG. 28 is a schematic side view illustration of a memory die stack with vertically aligned memory dies with different thicknesses in accordance with an embodiment.

FIG. 29A is a schematic top layout view illustration of a processor including edge PHY regions and a central compute region in accordance with an embodiment.

FIG. 29B is a schematic cross-sectional side view illustration of a memory system including a processor with surface mounted memory die stacks in accordance with an embodiment.

FIG. 30A is a schematic top layout view illustration for a wafer area supporting an array of compute regions and memory die stacks from which a plurality of integrated processors can be scribed in accordance with an embodiment.

FIGS. 30B-30C are schematic cross-sectional side view illustrations of integrated processors which have been scribed from the wafer of FIG. 30A in accordance with embodiments.

FIG. 31A is a schematic top layout view illustration for a wafer area supporting an array of compute regions and memory die stacks and PDN bridges from which a plurality of integrated processors can be scribed in accordance with an embodiment.

FIGS. 31B-31C are schematic cross-sectional side view illustrations of memory systems including a processor with surface mounted memory die stacks and PDN bridges in accordance with embodiments.

FIG. 32 is a schematic top layout view illustration of a scalable memory system with communication bars in accordance with an embodiment.

### DETAILED DESCRIPTION

Embodiments describe memory systems, such as HBM systems, and methods of fabrication that may facilitate increased capacity and bandwidth.

In one aspect, it has been observed that total memory capacity and bandwidth of conventional memory systems can be limited by the processor shoreline (edge length). Conventionally as many memory packages (each with a designated buffer die and memory die stack) as feasible are placed along the shoreline, generally this is one deep. As such, memory package depth can be roughly equal to the processor shoreline. Each memory package may conventionally also include a designated buffer base die. The buffer base die can include circuitry for traditional HBM, including physical layer (PHY) circuitry for transmitting and receiving data (such as serialization/descrialization (SerDes), buffering), memory (e.g., DRAM) control circuitry, and various miscellaneous circuitry (such as error correction and test).

In some embodiments buffer base dies are customized to receive multiple memory die stacks and into include internal network routing between the multiple memory die stacks, logic and timing. In this manner the memory system can realize increased capacity. Likewise, peak bandwidth can be scaled by providing alternative connections to a single memory die stack.

In some embodiments bandwidth and capacity can be scaled with implementing wafer-on-wafer bonding techniques. For example, hybrid bonding can be utilized to increase pad pitch.

In some embodiments bandwidth and capacity can be scaled with implementing custom local interconnects (or buffer bridges). For example, custom local interconnects can be utilized to offload processor die physical layer (PHY) circuitry thereby increasing the processor compute capability and reducing die-to-die routing length. Bandwidth may be further increased by reducing die-to-die interconnect length.

In some embodiments, bandwidth and capacity can be scaled with vertically arranged memory die stacks. In such a configuration bandwidth may be increased with reduced die-to-die routing length and additional on-chip routing capability, and capacity can be increased by packing more memory dies into available footprint.

The processor in accordance with embodiments can include a central processing unit (CPU), graphics processing unit (GPU), artificial intelligence (AI) accelerator, neural network processor, system on chip (SoC), or other unit that processes data. Memory die stacks in accordance with embodiments may be DRAM die stacks for HBM for example, though are not so limited. The number of memory dies may be 8, 12, etc. depending upon the generation of the memory system. The buffer base die in accordance with embodiments can include circuitry for traditional HBM, including physical layer (PHY) circuitry for transmitting and receiving data (such as serialization/deserialization (SerDes), buffering), memory (e.g., DRAM) control, and various miscellaneous circuitry (such as error correction and test. The buffer base dies in accordance with embodiments may additionally include internal network routing between the plurality of memory die stacks, as well as associated logic and retiming circuitry. In this manner, a specific network can be connected to any of, or all, of the memory die stacks for increased capacity. In some embodiments, the buffer base die can include repeaters and/or redrivers/retimers for longer channel reach. Inclusion of network routing options between the multiple memory die stacks can additionally leverage fine processing conditions and capabilities associated with active silicon fabs allowing for longer channel lengths and increased bandwidth (compared to conventional interposer routing) and additional rows of memory die stacks supporting increased capacity. This can additionally allow for more control over memory management and allow for heterogenous memory solutions (e.g., HBM and DDR).

In various embodiments, description is made with reference to figures. However, certain embodiments may be practiced without one or more of these specific details, or in combination with other known methods and configurations. In the following description, numerous specific details are set forth, such as specific configurations, dimensions and processes, etc., in order to provide a thorough understanding of the embodiments. In other instances, well-known semiconductor processes and manufacturing techniques have not been described in particular detail in order to not unnecessarily obscure the embodiments. Reference throughout this specification to “one embodiment” means that a particular feature, structure, configuration, or characteristic described in connection with the embodiment is included in at least one embodiment. Thus, the appearances of the phrase “in one embodiment” in various places throughout this specification are not necessarily referring to the same embodiment. Furthermore, the particular features, structures, configurations, or characteristics may be combined in any suitable manner in one or more embodiments.

The terms “above”, “over”, “to”, “between”, “spanning” and “on” as used herein may refer to a relative position of one layer with respect to other layers. One layer “above”, “over”, “spanning” or “on” another layer or bonded “to” or in “contact” with another layer may be directly in contact with the other layer or may have one or more intervening layers. One layer “between” layers may be directly in contact with the layers or may have one or more intervening layers.

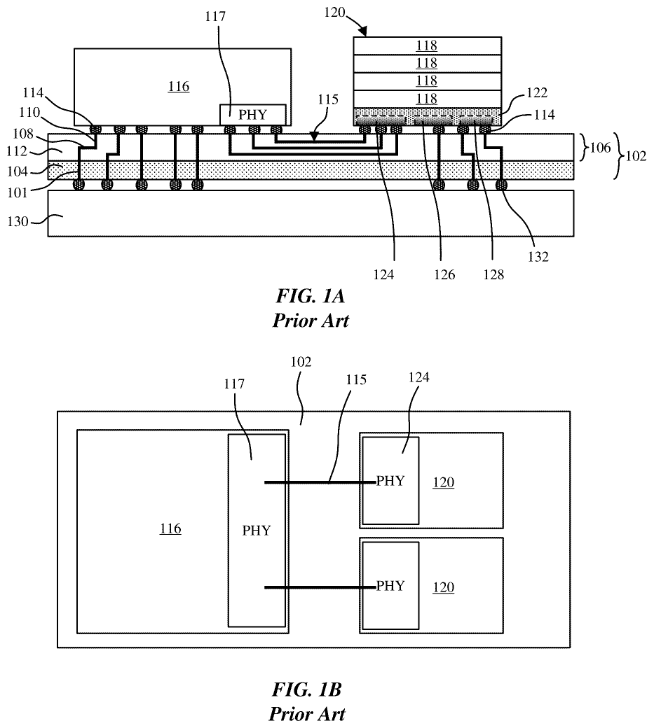

Referring now to FIG. 1A and FIG. 1B schematic cross-sectional side view and top layout view illustrations are provided for a conventional HBM system. As shown, this may include a silicon interposer 102 including a base silicon substrate 104 and routing layer 106 over the base silicon substrate. The routing layer may include a plurality of metal redistribution lines 108, vias 110 and dielectric layers 112. The various routing layers and vias may additionally form die-to-die routing 115 between a memory package 120 and processor 116 which can both be flip chip mounted onto a same side of the silicon interposer 102 with solder bumps 114 (e.g., micro bumps). The memory package 120 may include a plurality of stacked memory dies 118, such a DRAM dies, and a buffer die 122. Specifically, the die-to-die routing 115 may connect physical layers (PHY) 117, 124, as abstraction layers, that transit and receive data between the processor 116 and memory die package 120. For example, the PHYs 117, 124 can encode data for transmission and decode received data with a specific modulation speed of operation, transmission media type and supported link length. The buffer die 122 can additionally include memory control circuitry 126, as well as additional miscellaneous circuitry 128 (e.g., correction and test).

The silicon interposer 102 may additionally include through vias 101, such as through silicon vias (TSVs), for back side connection with a system substrate 130, such as a printed circuit board (PCB). For example, connection may be with a plurality of solder bumps 132, pins, etc. The system substrate can be a package substrate or substrate for larger module including additional components mounted thereon. As shown, electrical routing within the silicon interposer 102 can provide direct connection between the system substrate 130 and the processor 116 and/or memory package 120 (e.g., HBM), as well as the die-to-die routing 115.

Referring now to FIG. 2, a schematic cross-sectional side view illustration is provided of a memory system 100 with active buffer base die 140 in accordance with an embodiment. As shown, the memory system includes a routing substrate 134, a processor 116 on a first side of the routing substrate, a buffer base die 140 on the first side of the routing substrate 134, and a plurality of memory die stacks 150 on the buffer base die. The buffer base die 140 may additionally include network routing 125 connected to plurality of memory die stacks 150. The buffer base die 140 may include traditional circuitry such as physical layer (PHY) 124 circuitry (e.g., buffering circuitry, SerDes circuitry), memory control circuitry 126 (e.g., DRAM control), and miscellaneous circuitry 128 (e.g., error correction circuitry, test circuitry). The buffer base die 140 can additionally include network routing circuitry 142 to transmit signals between the processor 116 and the multiple memory die stacks through the network routing 125. In this manner capacity can be increased by connecting multiple memory die stacks 150 to the processor 116. Likewise, peak bandwidth can be scaled by providing alternative connections to a single memory die stack. Additionally, the custom internal network routing 125 can provide redundancy to memory die stacks 150.

In accordance with embodiments, the active buffer base die 140 not only can include traditional buffer die 122 circuitry, but can also offload certain buffer PHY circuitry (e.g., buffering circuitry, SerDes circuitry) of the processor 116. As such the processor 116 illustrated in FIG. 2 can include a custom die-to-die PHY 117B with enhanced feature such as smaller area, higher bandwidth density, and better power efficiency compared to a conventional processor PHY 117 of FIG. 1A. The smaller area is significant in that this can provide more available area for the main processor core. Specifically, the custom die-to-die PHY 117B may no longer be a high bandwidth memory PHY including both die-to-die interface logic, buffering circuitry, SerDes circuitry, etc. Instead, the custom die-to-die PHY 117B may be a simplified PHY with die-to-die interface logic. The other buffer PHY circuitry (e.g., buffering circuitry, SerDes circuitry) can optionally be relocated to PHY 124 circuitry of the buffer base die 140.

Still referring to FIG. 2, in the illustrated embodiment each memory die 118 may include through silicon vias (TSVs) 136 and micro bumps 138 (e.g., solder micro bumps) for vertical interconnection and stacking, and bonding to the buffer base die 140. The memory dies 118 may also be hybrid bonded to one another and/or to landing pads 143 of the buffer base die 140. In accordance with embodiments, the buffer base die 140 and processor 116 can be connected with the routing substrate 134 with solder bumps, or be hybrid bonded with the routing substrate 134 with metal-metal bonds with landing pads 144 and dielectric-dielectric bonds. Hybrid bonding may be implemented to increase the number of memory dies in a the memory die stacks, and also to reduce landing pad 144 pitch of the buffer base die 140, which can translate to reduced die-to-die routing 115 length, and consequently increased bandwidth.

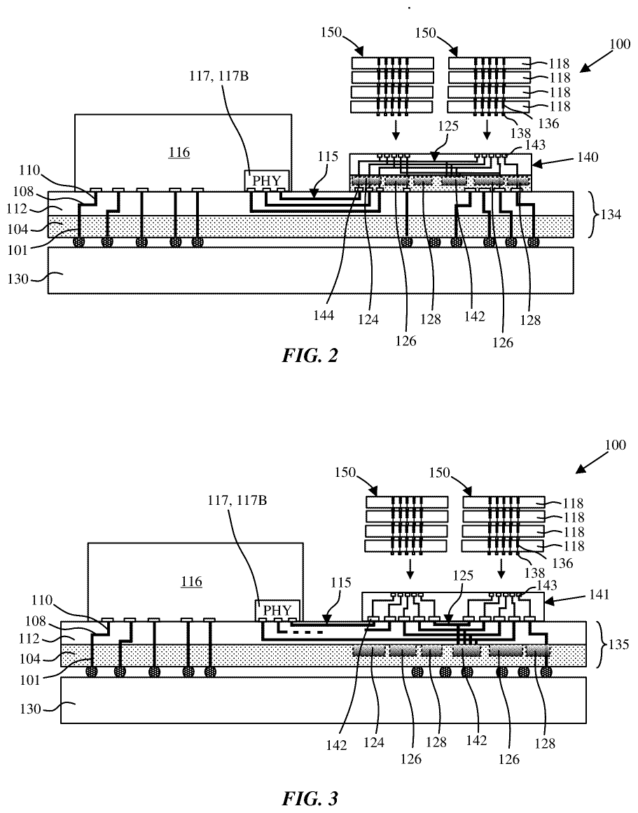

FIG. 3 is a schematic cross-sectional side view illustration of a memory system 100 with active routing substrate 135 in accordance with an embodiment. The arrangement of FIG. 3 is similar to that of FIG. 2 with instead buffer logic and routing is located within the active routing substrate, and the buffer die of FIG. 2 is replaced with a passive interposer. As shown, the memory system includes an active routing substrate 135, a processor 116 on a first side of the active routing substrate 135, a passive interposer 141 on the first side of the active routing substrate 135, and a plurality of memory die stacks 150 on the passive interposer 141. The active routing substrate 135 may include network routing 125 connected to plurality of memory die stacks 150. The active routing substrate 135 may include traditional circuitry such as physical layer (PHY) 124 circuitry (e.g., buffering circuitry, SerDes circuitry), memory control circuitry 126 (e.g., DRAM control), miscellaneous circuitry 128 (e.g., error correction circuitry, test circuitry), and network routing circuitry 142 to transmit signals between the processor 116 and the multiple memory die stacks through the network routing 125. The passive interposer 141 may be bonded to the active routing substrate 135 with solder bumps or hybrid bonding for example. The passive interposer 141 may be formed of suitable materials such as glass, silicon, etc. and may have a plurality of through vias, such as through glass vias, TSVs, etc. In another variation the memory die stacks 150 can be bonded directly to the active routing substrate 135.

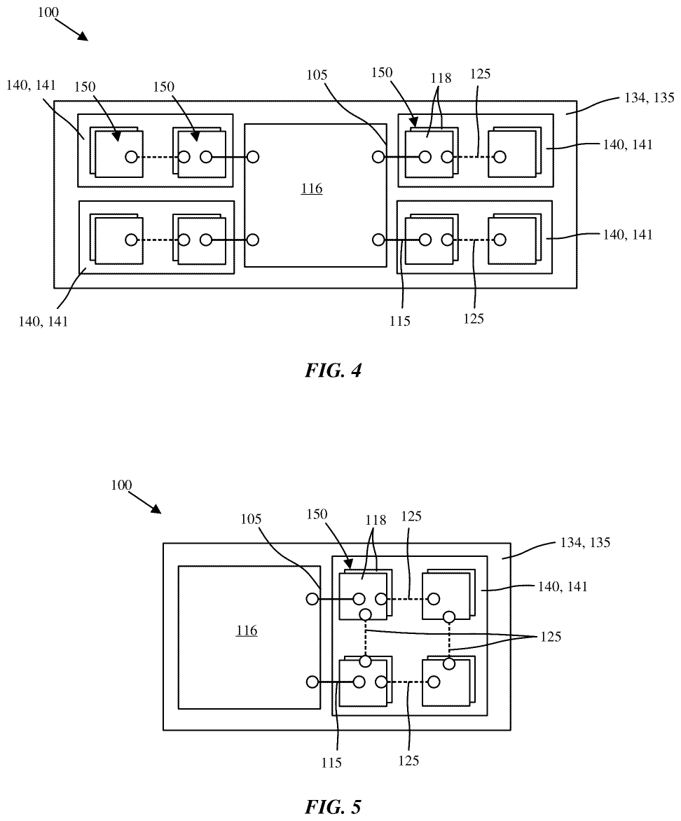

FIG. 4 is a schematic top layout view illustration of a memory system including a row of memory die stacks 150 on a buffer base die 140 or passive interposer 141 in accordance with an embodiment. As shown, each buffer base die 140 or passive interposer 141 can be a continuous substrate onto which multiple memory die stacks 150 are mounted. Die-to-die routing 115 connectivity may be standards based (e.g., HBMx) or as described herein as a custom high bandwidth interface. With reference to the traditional memory system illustrated in FIG. 1B, the memory system of FIG. 4 can increase capacity by 2×. In an exemplary row of memory die stacks 150, a first memory die stack 150 is laterally between a second memory die stack and a first edge 105 of the processor 116. There may also be multiple rows of buffer base dies 140. As shown, a third and fourth memory die stacks 150 can be arranged on a second buffer base die 140, with the third memory die stack laterally between the fourth memory die stack and the first edge 105 of the processor 116 with network routing 125 of the second buffer base die 140 or active routing substrate 135 connecting the third memory die stack and the fourth memory die stack. It is to be appreciated that while arrangement of memory die stacks, buffer base dies, etc. is specifically described and illustrated herein with regard to a first side of a processor 116, that such arrangements may be provided along multiple or all side edges of a processor. For example, memory die stacks 150 and buffer base dies 140 or passive interposers 141 are illustrated as being located along opposite sides of a processor 116 in FIG. 4. In sake of conciseness, the following description and illustrations may be made with regard to a single side of a processor, though it is to be appreciated that embodiments are not so limited, and such arrangements may be made along multiple or all sides.

FIG. 5 is a schematic top layout view illustration of a memory system including rows and columns memory die stacks 150 on a buffer base die 140 or passive interposer 141 in accordance with an embodiment. As shown, the buffer base die 140 or passive interposer 141 can be a continuous substrate onto which multiple memory die stacks 150 are mounted. With reference to the traditional memory system illustrated in FIG. 1B, the memory system of FIG. 4 can increase capacity by 2×, and up to a 4× instantaneous or peak bandwidth if all data is sent out of a single memory die stack 150. Further, if die-to-die routing 115 is a custom interconnect supporting very high bandwidth (e.g. 4-8× of HBM bandwidth then there is ample bandwidth per stack. The custom interconnect (PHY+wiring) can be dense saving area on the processor 116. If the illustrated embodiment includes a passive interposer 141, the memory die stacks 150 may also include dedicated buffer dies 122 (similar to FIG. 1A), or an active routing substrate 135 may include physical layer (PHY) 124 circuitry (e.g., buffering circuitry, SerDes circuitry), memory control circuitry 126 (e.g., DRAM control), miscellaneous circuitry 128 (e.g., error correction circuitry, test circuitry), and network routing circuitry 142 (similar to FIG. 3).

In an exemplary column of memory die stacks 150 a first memory die stack 150 and a second memory die stack 150 can be arranged side-by-side adjacent to the first edge 105 of the processor 116. Network routing 125 of the buffer base die 140 or active routing substrate 135 can be used to connect the vertically and horizontally adjacent memory die stacks 150, and possibly diagonally arranged memory die stacks.

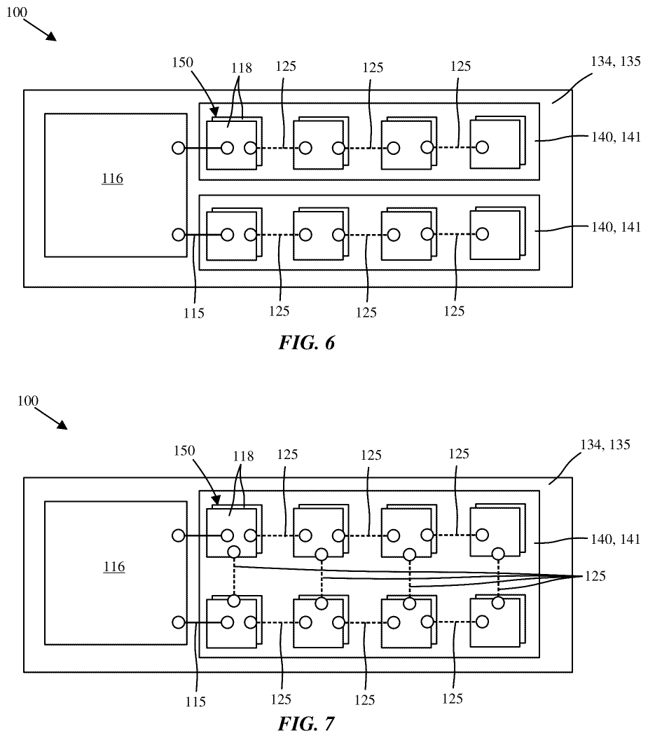

FIG. 6 is a schematic top layout view illustration of a memory system including a row of memory die stacks 150 on a buffer base die 140 or passive interposer 141 in accordance with an embodiment. As shown, each buffer base die 140 or passive interposer 141 can be a continuous substrate onto which multiple memory die stacks 150 are mounted. With reference to the traditional memory system illustrated in FIG. 1B, the memory system of FIG. 6 can increase capacity by 4×. Further, if die-to-die routing 115 is a custom interconnect supporting very high bandwidth (e.g. 4-8× of HBM bandwidth, then there is ample bandwidth per stack. If the illustrated embodiment includes a passive interposer 141, then the passive interposer may include improvements, buffer dies 122 (similar to FIG. 1A) can be included for each memory die stack 150 and include features to restore signals for correct functioning, or an active routing substrate 135 may include physical layer (PHY) 124 circuitry (e.g., buffering circuitry, SerDes circuitry), memory control circuitry 126 (e.g., DRAM control and data path), miscellaneous circuitry 128 (e.g., error correction circuitry, test circuitry), and network routing circuitry 142 (similar to FIG. 3).

FIG. 7 is a schematic top layout view illustration of a memory system including rows and columns memory die stacks 150 on a buffer base die 140 or passive interposer 141 in accordance with an embodiment. As shown, the buffer base die 140 or passive interposer 141 can be a continuous substrate onto which multiple memory die stacks 150 are mounted. With reference to the traditional memory system illustrated in FIG. 1B, the memory system of FIG. 7 can increase capacity by 4×, and up to an 8× instantaneous or peak bandwidth if all data is sent out of a single memory die stack 150. Further, if die-to-die routing 115 is a custom interconnect supporting very high bandwidth (e.g. 4-8× of HBM bandwidth, then there is ample bandwidth per stack. If the illustrated embodiment includes a passive interposer 141, then networking function will need to be provided by buffer dies 122 (similar to FIG. 1A) for each memory die stack 150, or an active routing substrate 135 may include physical layer (PHY) 124 circuitry (e.g., buffering circuitry, SerDes circuitry), memory control circuitry 126 (e.g., DRAM control and data path), miscellaneous circuitry 128 (e.g., error correction circuitry, test circuitry), and network routing circuitry 142 (similar to FIG. 3).

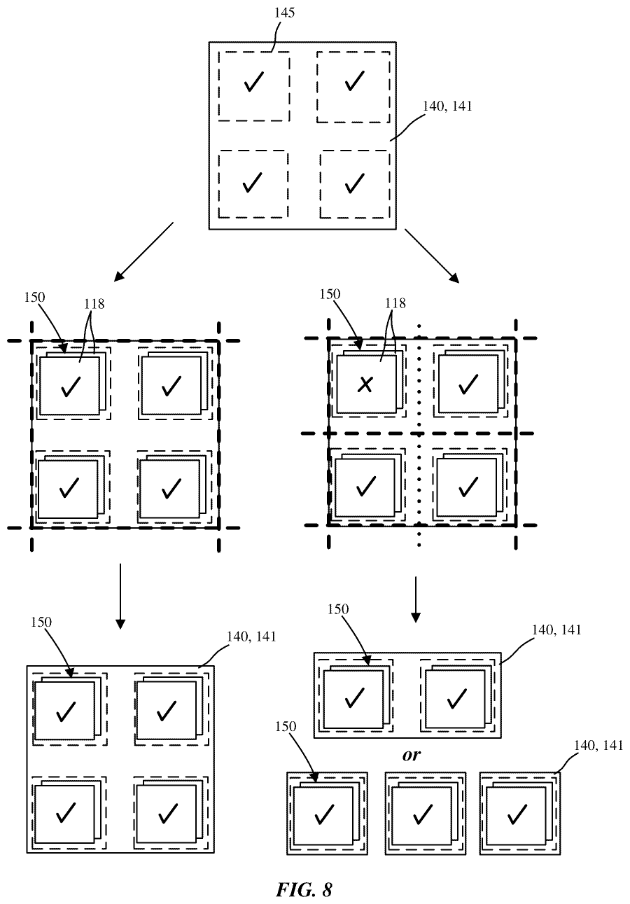

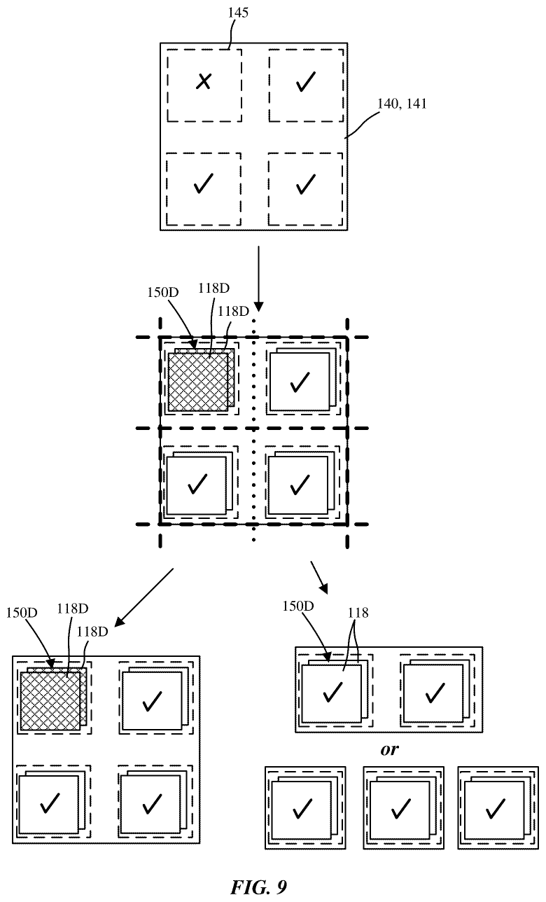

In accordance with embodiments wafer-on-wafer or chip-on-wafer fabrication techniques may be utilized to form the memory die stacks 150 and/or integrated buffer base dies 140 or passive interposers 141. FIGS. 8-9 are process flows for sequences of harvesting integrated buffer base dies 140 or passive interposers 141 in accordance with embodiments. As shown, the sequence may begin at the wafer level with a buffer wafer including various areas 145 for buffer base dies 140 or passive interposers 141, with each area 145 cither including routing or buffer die supporting circuitry such as PHY 124, memory control circuitry 126, miscellaneous circuitry 128, network routing circuitry 142. Each area 145 can then be tested for functionality, with a passing test indicated with check mark and failing test indicated by an x mark. Each area 145 is shown as functional in FIG. 8 while one area is indicated as failing in FIG. 9. At this point a wafer including a corresponding array of memory dies 118 can be bonded to the buffer wafer. Alternatively, a plurality of memory dies 181 can be bonded to the buffer wafer. This may be followed by second-level bonding of additional memory dies 118 at the wafer or chip-level, followed by additional levels until the desired memory die stack height is achieved. Where all areas 145 and memory dies 118 are determined to be good, larger area buffer base dies 140 or passive interposers 141 can be scribed including a larger number of memory die stacks 150. Alternatively, where a bad area 145 or memory die 118 is detected, as indicated by the x mark, smaller area buffer base dies 140 or passive interposers 141 can be scribed out for different applications requiring lower capacity. In the process flow provided in FIG. 8, a defective memory die is not detected until the end of the memory die stacking sequence. In the process flow provided in FIG. 9, a defective area 145 is detected prior to the memory die stacking process. As shown, dummy memory dies 118D can be stacked onto a known defective area 145 to form dummy memory die stacks 150D. It is to be appreciated that a defective memory die 118, and hence defective memory die stack 150, can still be retained in a final product, where the processor (controller) is programmed to avoid utilization of the defective memory die or memory die stack. This redundancy is shown at a stack level. It may be possible to have a memory stack that supports many channels. In such a case redundancy at a channel level may be used. Further, extra memory stacks or channels may be provided to address failures during normal product operation i.e. in the field defect.

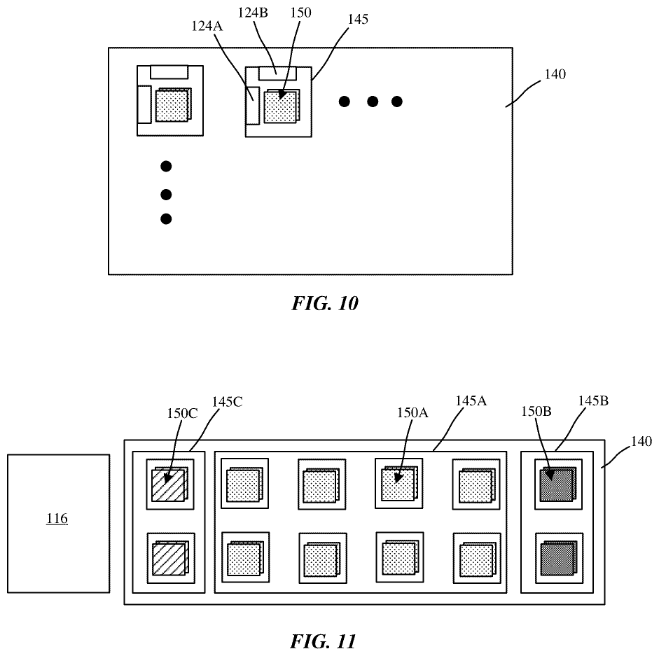

FIG. 10 is a schematic top layout view illustration of an active buffer base die with double sided PHY area in accordance with an embodiment. As shown, each area 145 of the active buffer base die 140 can support a memory stack 150 and include segregated die-to-die PHY 124A region and SerDes PHY 124B region, which may be along different edges/sides of the areas 145. In such a case, an arrayed memory stack may be supported using die-to-die PHY 124. In case of individual buffer needs, or dicing (e.g., due to harvesting), SerDes PHY 124B can provide individual memory stack usage.

FIG. 11 is a schematic top layout view illustration of an active buffer base die 140 with checkpoint features in accordance with an embodiment. As shown, the active buffer base die 140 can include a scalable memory solution area 145A for first memory die stacks 150A and a checkpoint area 145B for second memory die stacks 150B. For example, the second memory die stacks 150B can be a different type of memory, including non-volatile memory (such as NAND storage) and/or volatile memory (such as XRAM). The second memory die stacks 150B can have a lot of capacity if needed by the system and may also provide high bandwidth. Another function is as a checkpoint, or model/data storage that saves the system configuration and data, and in case if data from the first memory die stacks 150B is lost when the system goes down, the checkpoint data can be used to restore and recover. In an embodiment the active buffer base die 140 includes a storage area 145C (e.g., for caching, checkpoint, or model storage) where third memory die stacks 150C can be provided to increase bandwidth, energy, and lower latency. Such caching may be inserted in the custom buffer (single or arrayed). In addition, the caching function may be in the active buffer base die 140 or added as a layer in the second memory die stacks 150B.

Up until this point embodiments have been described in which each memory die stack does not include a corresponding buffer die. However, embodiments are not so limited. Furthermore, embodiments described up until this point have been described in which the processor 116 includes a corresponding physical layer (PHY) 117 or custom die-to-die PHY 117B. In accordance with embodiments, the die-to-die routing 115 length can be reduced by offloading data encoding components of the PHY 117 (e.g., SerDes, buffering) from the processor into the buffer base die, routing substrate, or other active local interconnect. Such a configuration can increase available active area within the processor 116, further reducing channel length, and thus increasing bandwidth.

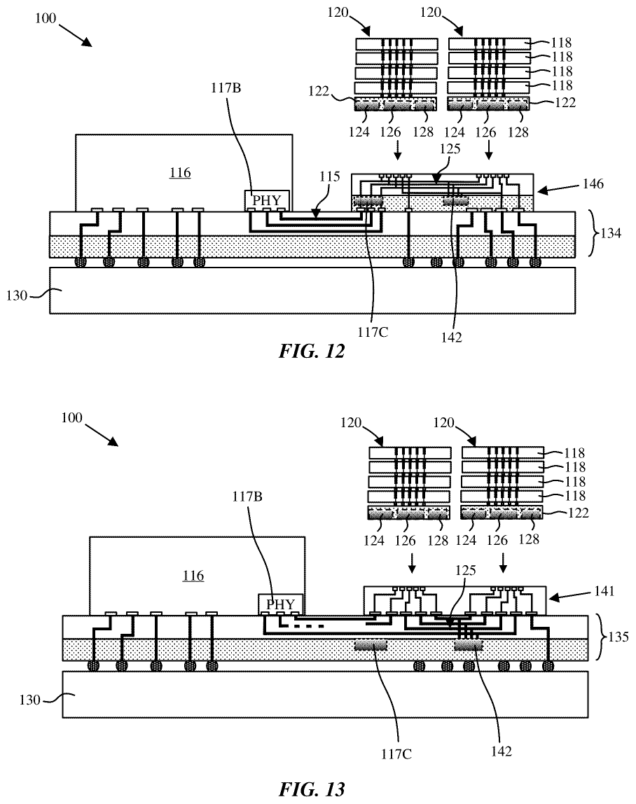

FIG. 12 is a schematic cross-sectional side view illustration of a memory system in which the processor 116 encoding PHY 117C logic is relocated within an active interposer 146 in accordance with an embodiment. The embodiment illustrated in FIG. 12 is similar to the configuration of FIG. 2, with some differences. Initially, the memory dies 118 are arranged in memory packages 120 includes corresponding buffer dies 122. Thus, the memory packages 120 may be traditional memory packages. The processor 116 of FIG. 12 is designed to not include the encoding PHY 117C logic, which is instead located within active interposer 146, upon which a plurality of memory packages 120 are mounted. In this configuration the die-to-die routing 115 length can be reduced. The active interposer 146 additionally includes network routing 125 and network routing circuitry 142 to transmit signals between the processor 116 and the multiple memory packages 120 through the network routing 125. In this manner, both system capacity and bandwidth can be increased as previously described while implementing conventional memory packages.

FIG. 13 is a schematic cross-sectional side view illustration of a memory system in which the processor 116 encoding PHY 117C logic is relocated within an active routing substrate 135 in accordance with an embodiment. The embodiment illustrated in FIG. 13 is similar to the configuration of FIG. 3, with some differences. Initially, the memory dies 118 are arranged in memory packages 120 includes corresponding buffer dies 122. Thus, the memory packages 120 may be traditional memory packages. The processor 116 of FIG. 13 is designed to not include the encoding PHY 117C logic, which is instead located within active routing substrate 135, upon which the passive interposer 141 is mounted. In this configuration the die-to-die routing 115 length can be reduced. The active routing substrate 135 additionally includes network routing 125 and network routing circuitry 142 to transmit signals between the processor 116 and the multiple memory packages 120 through the network routing 125. In this manner, both system capacity and bandwidth can be increased as previously described while implementing conventional memory packages.

In accordance with some embodiments capacity and bandwidth increases can be realized while also realizing assembly cost savings. It has been observed that active silicon-based component cost can be high, particularly when implementing the most recent technology nodes. In accordance with some embodiments organic routing substrates (e.g., interposers) can be utilized to reduce cost, while active or passive local interconnects (which can also be referred to as bridge dies or chiplets) can be added to supplement routing or logic function.

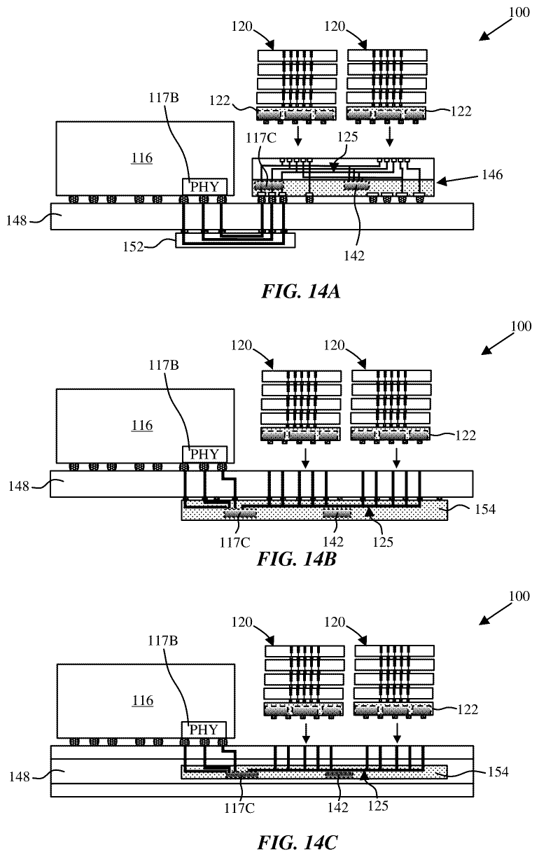

FIG. 14A is a schematic cross-sectional side view illustration of a memory system including an organic routing substrate 148 and backside passive local interconnect in accordance with an embodiment. The particular embodiment illustrated in FIG. 14A may be similar to that illustrated in FIG. 13 with a difference being that the routing substrate 134 of FIG. 8 can be replaced with an organic routing substrate 148 and passive local interconnect 152, which can be a silicon-based die. In this manner, a substantial portion of the die-to-die routing length can still be maintained in silicon-based technology, while the bulk organic substrate 148 can reduce cost compared to a silicon-based routing substrate of similar size. Since the routing substrate 148 is organic, then the processor and active interposer 146 and passive local interconnect 152 can be attached using fine pitch solder bumping, or even polymer/metal hybrid bonding. In some embodiments the passive local interconnect 152 can instead be an active local interconnect. In such a case, the custom die-to-die PHY 117B on processor 116 can also be optimized for bandwidth, area and energy.

FIG. 14B is a schematic cross-sectional side view illustration of a memory system including an organic routing substrate 148 and a backside active local interconnect 154 in accordance with an embodiment. The particular embodiment illustrated in FIG. 14B may be similar to that illustrated in FIG. 13 with a difference being that the optional passive interposer 141 is removed, and the active routing substrate 135 of FIG. 9 is replaced with an organic routing substrate 148 and active local interconnect 154, which can be a silicon-based die. In such an arrangement, the custom die-to-die PHY 117B may be optimized for area, energy, and bandwidth, whereas encoding PHY 117C logic is its counterpart. In this fashion, significant area can be saved from the processor 116 (core logic die), while providing a very high bandwidth.

FIG. 14C is a schematic cross-sectional side view illustration of a memory system including an organic routing substrate 148 and an embedded active local interconnect in accordance with an embodiment. FIG. 14C is similar to the embodiment of FIG. 14B, with the active local interconnect being embedded within the organic routing substrate 148 rather than being mounted on a backside thereof.

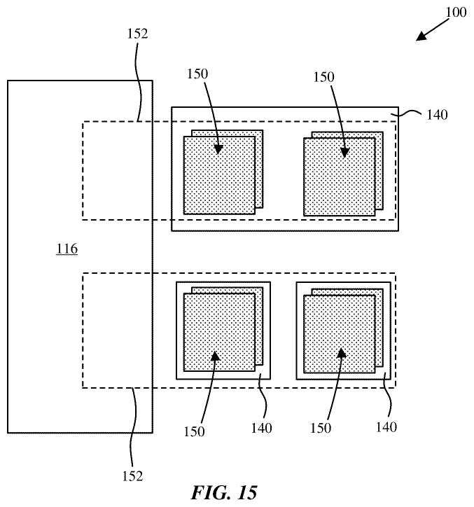

FIG. 15 is a schematic top layout view of a memory system with a passive local interconnect in accordance with embodiments. Two exemplary configurations are illustrated. In such embodiments the passive local interconnect 152 may include additional metallization layers compared to more common local interconnects. The passive local interconnect 152 may support die-to-die routing between the processor 116 and the active buffer base die(s) 140 and memory die stacks. In such configurations the memory die stacks 150 can have a shared buffer base die or individual buffer base dies 140. Here the passive local interconnects 152 may include 10-14 metal layers, such as 12 metal layers, compared to more common 4-6 metal layers. The additional metal layers can improve cross-talk, and have larger widths to improve RC timing and support longer lengths, such as greater than 15 mm. The active buffer base die(s) 140 similar to previous discussion can have advanced PHY components beyond normal high bandwidth memory PHY components. For example, the active buffer base die 140 can include signal enhancement circuitry (analog and digital), transceiver equalizer, receiver equalizer, improved clocking, operate at higher voltages and be fabricated with advanced technology nodes, e.g., 5 nm transistors.

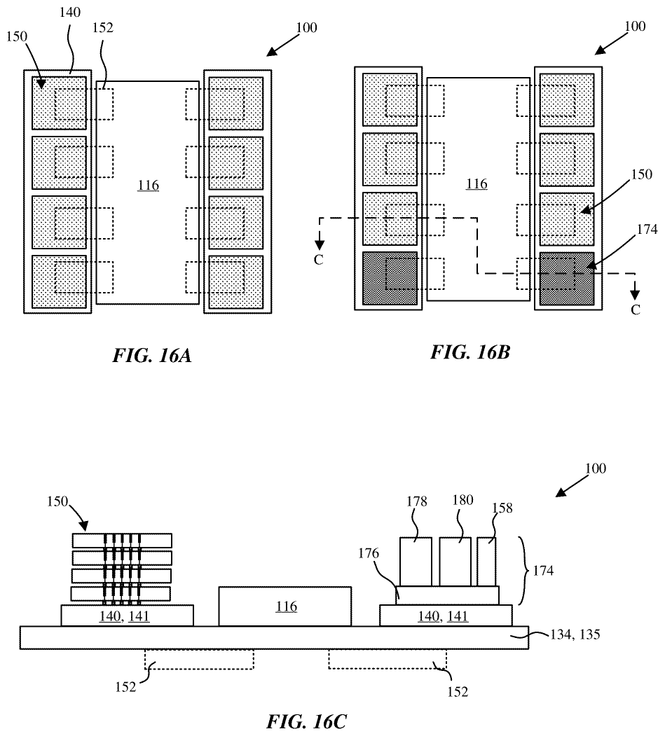

Referring now to FIGS. 16A-16B schematic top layout view illustrations are provided for memory systems with interchangeable memory or co-packaged optical engines 174 in accordance with embodiments. Specifically, FIG. 16A illustrates an active buffer base die 140 or passive interposer 141 in accordance with embodiments that is fully populated with memory stacks 150. FIG. 16B illustrates an active buffer base die 140 or passive interposer 141 in accordance with embodiments including some areas 145 populated with optical engines 174. FIG. 16C is a schematic cross-sectional view taken along section C-C of FIG. 16B in accordance with an embodiment. It is to be appreciated that the particular stack-up of FIG. 16C is exemplary, and arrangements of optical engines 174 can be integrated into any of the stack-ups described an illustrated herein for photonic coupling within the memory systems, or external photonic coupling outside of the memory systems. The co-packaged optical engines 174 in accordance with embodiments may have a similar top height as the memory die stacks 150 for compatibility with the rest of the system packaging.

Photonic coupling in accordance with embodiments may include photonic waveguides coupled with optical engines 174 that include one or more converters such as electrical-to-optical (EO) converters 178 and optical-to-electrical (OE) converters 180 and controller logic 176 (also referred to as conversion electronics). The photonic waveguides can be formed using a variety of suitable techniques and may include photonic wires (e.g., bundled fiber or formed using 3D multi-photon write, holographic write, micro-pen write, direct optical wire bonding, or a mix), or index defined patterns forms using techniques such as nano imprint (embossing), lithography, etc. Additional optics for coupling the optical transceivers (emitters) and optical receivers (detectors) with the photonic waveguides, such as lenses, grating couplers, mirrors, prisms, optical vias, etc. can also be formed using similar techniques. The controller logic 176 can include the necessary driving circuitry for the converter(s), and can optionally include additional components such as multiplexers, demultiplexers, modulators, buffers, etc. An EO converter 178 may include any suitable optical transmitter such as laser, light emitting diode, or other light source. An OE converter 180 may include an optical receiver such as a photodetector (avalanche photodiode, p-i-n photodiode, etc.). One or more optical repeater structures may additionally be included in the optical paths to receive, amplify, and then re-transmit the optical signals. One example is an optical amplifier (e.g. semiconductor optical amplifier). Other repeaters may be electrical/optical that can be integrated into active silicon connected to the optical paths with a variety of features such as logic, flops, cache, memory compressors and decompressors, controllers, local processing elements, etc.

The optical paths in accordance with embodiments can range from very short, to long reach, to extra-long reach. For example, shorter length applications can be intra-die or inter-die connections, such as die-edge to die-edge connections, such as 20 mm or less. Longer reach applications can include intra-die or inter-die connections such as die-core to die-core (core-to-core) connections. Exemplary lengths may be 20 mm-100 mm. Such longer reach applications may provide lower latency and energy requirements compared to electrical interconnects, particularly for high wiring density. Still longer reach applications, such as 50 mm to 10 m can include electrical and optical communication mixing, with connection possibilities not being limited to die peripheries, and can be from the die core point of use. Even longer reach applications, such as 1 meter to 1 kilometer or further may utilize higher power optical emitters such as lasers with modulators and multiplexers.

Still referring to FIGS. 16A-16C the optical paths can be waveguides formed within the various routing substrates, interposers, local interconnects, etc. for short reach applications within the memory system. Optical paths can also be external for longer reach applications. In such configurations, the optical engines 174 may further include connectors 158. Connectors 158 can be any suitable type depending upon application, such as lucent connectors (LC), standard connectors (SC), ST connectors, ferrule core (FC) connectors, multi-position optical (MPO) connectors, MT-RJ connectors, or multi-fiber (new connectors), etc. and may be designed to transmit and receive optical data.

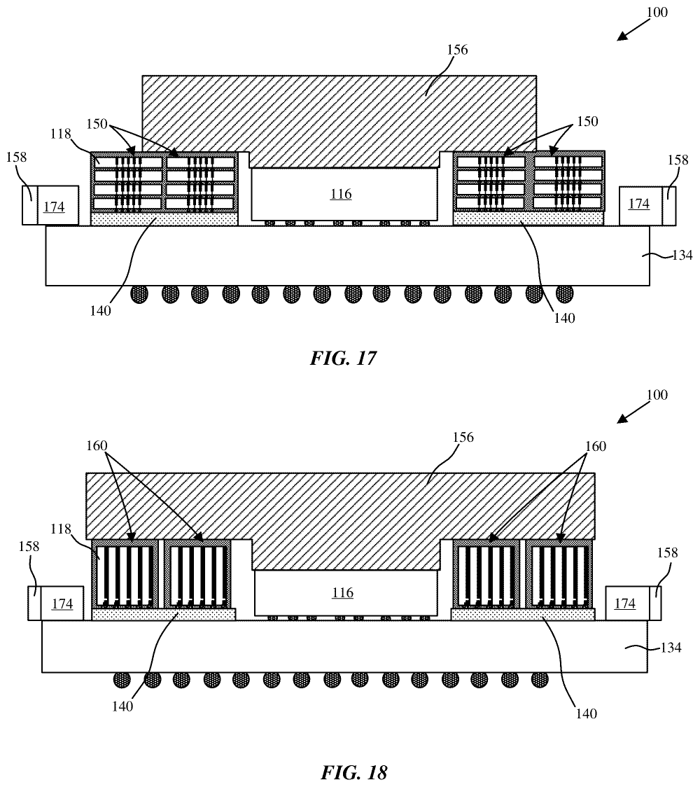

FIG. 17 is a schematic cross-sectional side view illustration of a memory system 100 with an active buffer base die and horizontally aligned memory dies in accordance with an embodiment. The embodiment illustrated in FIG. 17 is substantially similar to that shown in FIG. 2 with addition of a thermal solution 156 (e.g., lid, heat spreader), and optional optical engines 174 with optical connectors 158.

FIG. 18 is a schematic cross-sectional side view illustration of a memory system with an active buffer base die and vertically aligned memory dies in accordance with an embodiment. FIG. 18 is substantially similar the arrangement of FIG. 17 with a difference being vertically aligned memory dies 118 into vertical memory die stacks 160. Such a configuration may be utilized to increase memory die density per area footprint (x,y). For example, this may be achieved with die thinning techniques, which can increase capacity as well as bandwidth gain due to reduced routing distances. The vertically oriented memory dies 118 may be bonded together with micro bumps or hybrid bonded. Vertical alignment may further take advantage of existing die routing layers for vertical routing. This may also allow reducing memory die width dimensions to fit additional rows of memory die stacks adjacent a processor 116 edge for increased bandwidth.

While the optical engines 174 are illustrated in FIGS. 17-18 as being mounted onto the routing substrate 134, the optical engines 174 may alternatively be mounted onto the buffer base die 140 similarly as shown in FIGS. 16B-16C.

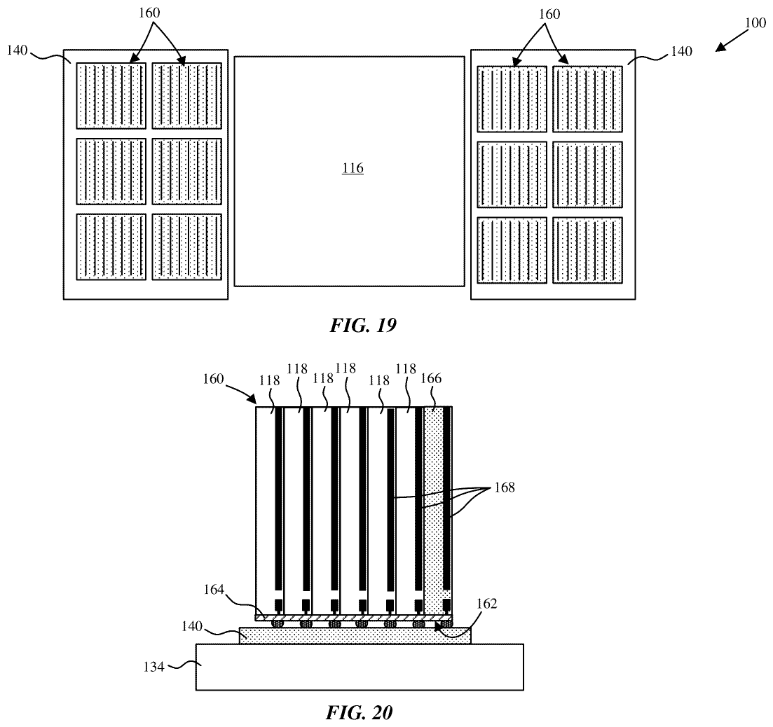

FIG. 19 is a schematic top layout view illustration of a memory system 100 including a plurality of memory die stacks 160 with vertically aligned memory dies on a buffer base die 140 in accordance with an embodiment. FIG. 20 is a close-up schematic cross-sectional side view illustration of a memory die stack 160 with vertically aligned memory dies 118 on a buffer base die 140 in accordance with an embodiment. Such a configuration may be similar to that previously described and illustrated with regards to FIGS. 4-7 where the buffer base die 140 may optionally include internal network routing 125 to communicate with the various vertical memory die stacks 160. In an embodiment, a memory system includes a processor 116 and a memory die stack 160 operably connected with the processor 116, the memory die stack including a bonding surface 162 and plurality of memory dies 118 oriented orthogonal to the bonding surface. For example, the processor 116 can be mounted on a first side of a routing substrate 134, and the bonding surface 162 is also mounted on the first side of the routing substrate 134. In an embodiment the memory system 100 further includes a buffer base die 140, and the memory die stack is mounted on a top side of the buffer base die 140, which is mounted on the first side of the routing substrate. In an embodiment a plurality of memory die stacks 160 is mounted on the top side of the buffer base die 140. The buffer base die 140 may perform similar functions as described herein. For example, the buffer base die can include network routing circuitry 142 to transmit signals between the processor and any of the multiple memory die stacks 160 through network routing 125, or to more than one or all of the memory die stacks 160 through network routing 125.

Still referring to FIG. 20, the memory die stack 160 may optionally include a bottom side routing layer 164 to facilitate connection with the memory die 118 back-end-of-the-line (BEOL) wiring layers 168 and the buffer base die 140, for example, with solder bumps 114 (e.g., micro bumps) or hybrid bonding. In accordance with embodiments, the vertical stacking of memory dies 118 can leverage the existing BEOL wiring layers 168. In this arrangement, traditional wire bonding or TSVs between memory dies can be avoided, thus improving design simplicity and memory die density (footprint density, GB/mm²). An additional side buffer die 166 parallel with the memory dies 118 can optionally be included. Where side buffer dies 166 are included, the buffer die 140 shown in FIG. 20 may more functionally resemble active interposer 146.

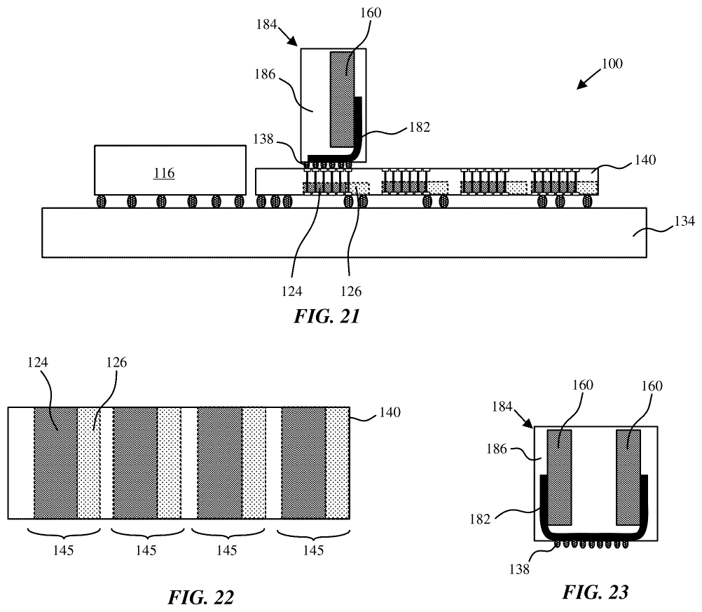

Referring now to FIG. 21 a schematic cross-sectional side view illustration is provided for a memory system 100 including a buffer base die 140 designed to receive a plurality of die stacks 160 with vertically oriented memory dies. The memory die stacks 160 may be similarly arranged such as described with regard to FIG. 20, with the addition of a flexible routing substrate 182 that may be passive or active. Specifically, the memory package 184 can be realized by mounting the memory die stacks 160 onto a first side of a flexible routing substrate 182 (for example, with micro bumps), optionally encapsulating the memory die stacks 160 on the flexible routing substrate 182 with a molding compound 186, and mounting a back side of the flexible routing substrate 182 onto the buffer die 140 with a plurality of micro bumps 138 (or larger solder bumps, etc.). A schematic top view illustration of the plurality of areas 145 of the buffer base die 140 is shown in FIG. 22. As shown in FIGS. 21-22 each area 145 can include at least a PHY 124 circuitry and memory control circuitry 126. Multiple memory die stacks 160 can be mounted on the flexible routing substrates 182. For example, a folded die stack arrangement can be included within a memory package 184 as shown in FIG. 23.

While vertical orientation of memory dies 118 in accordance with embodiments may facilitate densification and capacity increase, this may present challenges associated with assembly and reliability, thermal issues, and power delivery issues. Such challenges may be addressed in accordance with embodiments by distributing read/write signals among the vertically oriented memory dies 118 so that high temperature processes are not concentrated in one memory die deep within x, y, z location within the stack, on-chip BEOL wiring layers for thermal assist and power delivery, distributed temperature sensors within the memory die stack, gaps in the stack to allow for cooling, periodic insertion of thermal channels, and variable memory die thickness.

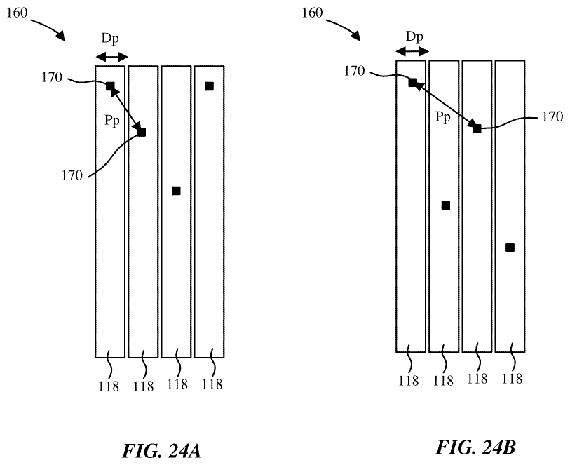

FIGS. 24A-24B are schematic bottom view illustrations of read/write contact pads for a memory die stack with vertically aligned memory dies in accordance with embodiments. Specifically, FIGS. 24A-24B are bottom bump-side view illustrations for an arrangement that can facilitate assembly of thin memory dies 118, with tight stacking pitch, by relaxing pad pitch (e.g., solder bump 114 pitch) such that it is greater than the memory die 118 stacking pitch. As shown, the smallest pad pitch (Pp) is greater than the smallest memory die pitch (Dp). Such a configuration may be characterized by not locating pads 170 at the same location for immediately adjacent memory dies 118. Thus, the closest pad pitch (Pp) is diagonally oriented. Such a configuration may trade potential memory bus width for a relaxed pad pitch and easier assembly. For more relaxed distances the closest diagonal orientation may span across multiple memory dies 118 as shown in FIG. 24B.

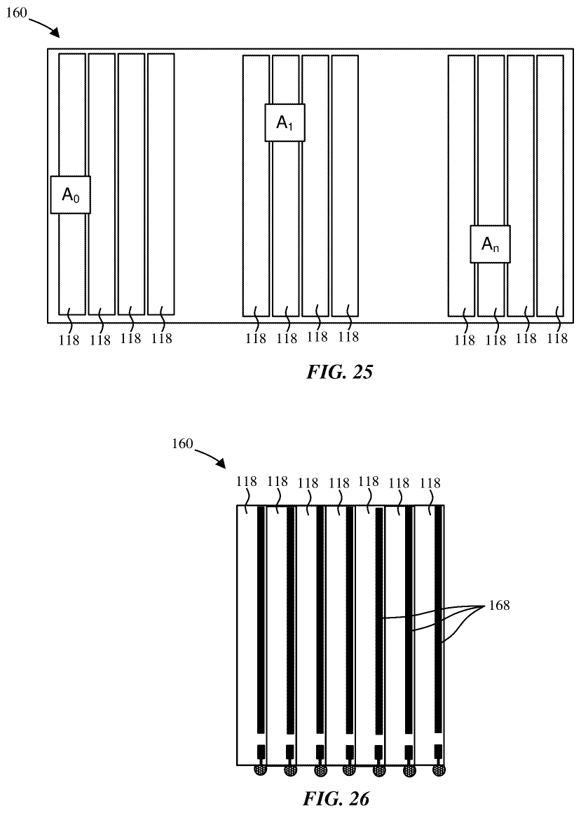

FIG. 25 is a schematic side view illustration of distributed activity within a memory die stack 160 with vertically aligned memory dies 118 in accordance with an embodiment. In particular, FIG. 25 illustrates location of concentrated activity A₀, A₁ . . . . Aₙ. In the particular embodiment illustrated, these locations are spread across the memory die stack 160 for distributed activity and thermal requirements. Furthermore, the memory dies 118 can be arranged in groups separated by spaces, with equal distribution of concentrated activity among the groups.

FIG. 26 is a schematic side view illustration of a memory die stack 160 with vertically aligned memory dies 118 with thermal paths in accordance with an embodiment. Specifically, the thermal paths may be parts of the BEOL wiring layers 168 that may additionally include metal planes for thermal distribution, for example near distributed read/write areas that can be locations of concentrated activity as discussed with regard to FIG. 25.

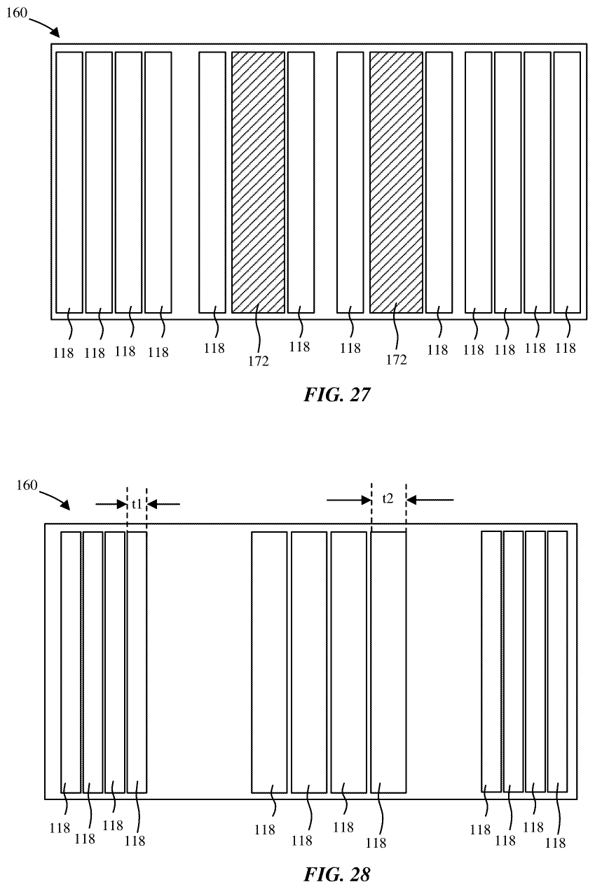

FIG. 27 is a schematic side view illustration of a memory die stack with vertically aligned memory dies 118 and thermal shims 172 in accordance with an embodiment. As shown, one or more thermal shims 172 (e.g., SiC, diamond, etc. layers) can be arranged between laterally adjacent memory dies 118 within the memory die stack 160. The thermal shims may be exposed to system level thermal solutions (e.g. heat sink, cooling loops etc.)

FIG. 28 is a schematic side view illustration of a memory die stack with vertically aligned memory dies with different thicknesses in accordance with an embodiment. As shown, the plurality of memory dies can be arranged in a first group of first memory dies with a first thickness (t1) and a second group of second memory dies with a second thickness (t2), wherein the first memory dies are thicker than the second group of memory dies. The memory dies 118 may additionally have gradual thicknesses within the stack. In both embodiments illustrated in FIG. 27 and FIG. 28 the thermal shims 172 and memory dies with the second thickness (t2) can be located within a center or interior of the memory die stack 160.

Up until this point the processors 116 and memory stacks 160 have been integrated separately into the memory systems. In other embodiments the memory die stacks 160 can be bonded directly to the processors 116 and integrated together. Furthermore, such the joined memory stacks 160 and processors can be fabricated at the wafer level, and diced together including various numbers of processor cores and integrated memory stack banks.

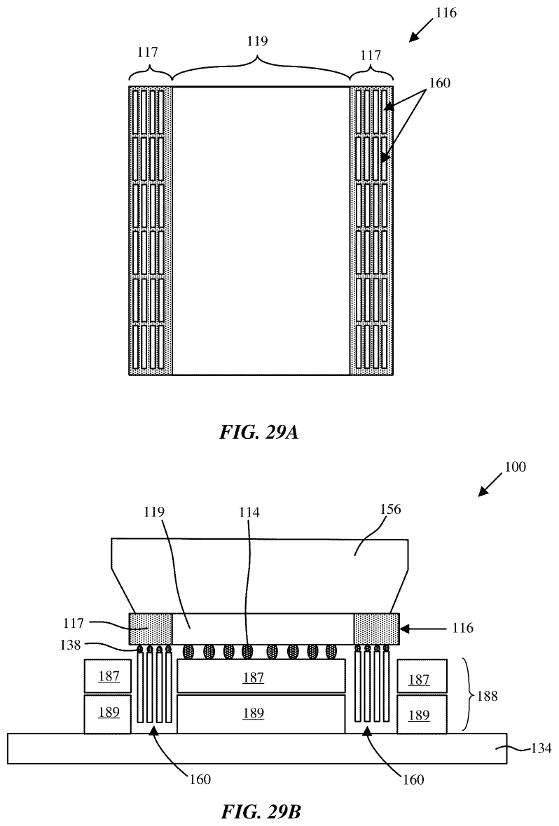

Referring now to FIGS. 29A-29B, FIG. 29A is a schematic top layout view illustration of a processor 116 including edge PHY 117 regions and a central compute 119 region; FIG. 29B is a schematic cross-sectional side view illustration of a memory system including a processor 116 with surface mounted memory die stacks 160 in accordance with an embodiment. As shown, the integrated processor 116 with memory die stacks 160 can be mounted faced down onto a connector 188 with openings (that can extend completely or partially through the connector 188) that can accommodate the memory die stacks 160. The connector 188 for example may include a top substrate 187 and socket 189 to mate with terminals of the top substrate 187, or vice versa. The memory die stacks 160 may be mounted on the processor 116 with micro bumps 138 while the processor 116 is mounted onto the connector 188 with solder bumps 114, though other bonding solutions are possible. Power delivery network (PDN) and mechanical attach solution can also be implemented with the connector 188. A thermal solution 156 (e.g., lid, heat spreader) can optionally be bonded to the back side of the processor 116. In the illustrated embodiment each memory die stack of the plurality of memory die stack includes a group of memory dies, with each memory die orthogonally oriented orthogonal to the processor.

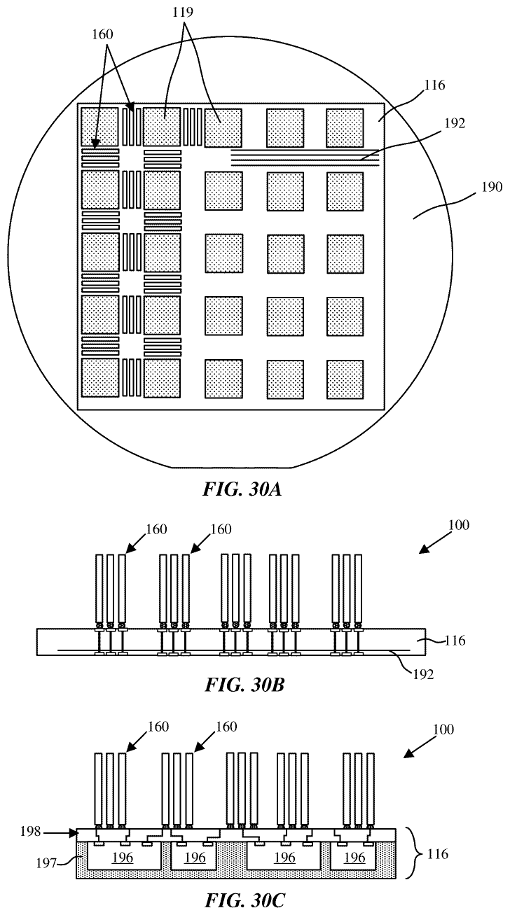

Referring now to FIG. 30A a schematic top layout view illustration is provided for a wafer 190 area supporting an array of compute 119 regions and memory die stacks 160 from which a plurality of integrated processors 116 can be scribed. The wafer 190 may be a silicon wafer, reconstituted wafer, or large panel for example. The array of compute 119 regions and areas supporting the memory die stacks 160 can be connected with fabric 192, formed of the various circuitries described herein (e.g., PHY, memory control circuitry, miscellaneous circuitry). FIG. 30B is a schematic cross-sectional side view illustration of an integrated processor 116 which has been scribed from the wafer 190 of FIG. 30A. Thus, memory integrations can be at the wafer scale, prior to singulation of processors 116. As shown, a plurality of memory die stacks 160 can be bonded to a wafer 190 supporting an array of compute 119 regions. The memory die stacks 160 can be placed at specific locations such as only around the perimeter of one, or a group of compute 119 regions, or distributed between adjacent compute 119 regions as illustrated, or both. Placement of the memory die stacks 160 around the wafer perimeter may be easier for power delivery network (PDN) integration, thermal and mechanical. Placement of the memory die stacks between the computer 119 regions may necessitate more careful consideration for PDN routing, thermal and mechanical.

While the embodiment shown in FIG. 30B is illustrated as being fabricated from wafer-scale, such as complementary metal-oxide semiconductor (CMOS) wafer, embodiments are not so limited and embodiments can also be fabricated from reconstituted substrates, which can be wafer-scale or panel-scale. Such reconstitution may be organic fanout type, or interposer based (e.g., with solder micro bumps), or using hybrid bonding. FIG. 30C is a schematic cross-sectional side view illustration of a memory system similar to that illustrated in FIG. 30B except the processor 116 is instead diced from a reconstituted substrate including a plurality of chiplets 196 embedded in a gap fill material 197 (e.g., molding compound, etc.) and connected with a redistribution layer (RDL) 198 which may include fanout wiring. In accordance with embodiments, the processor 116 may include a single chiplet 196 (or die), or include a plurality of chiplets 196, that may include different intellectual property (IP) blocks and/or be fabricated at different process nodes (e.g., transistor channel width, properties, metal stacks, etc.).

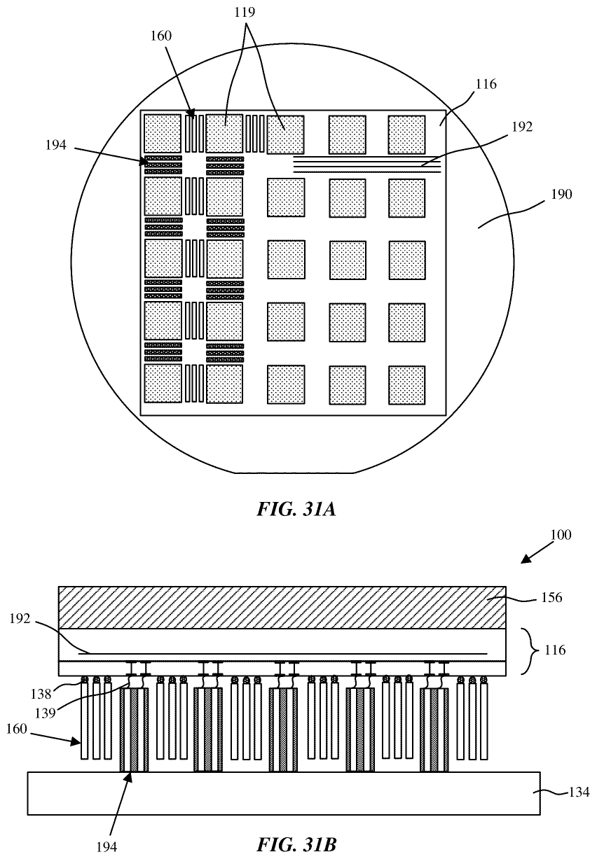

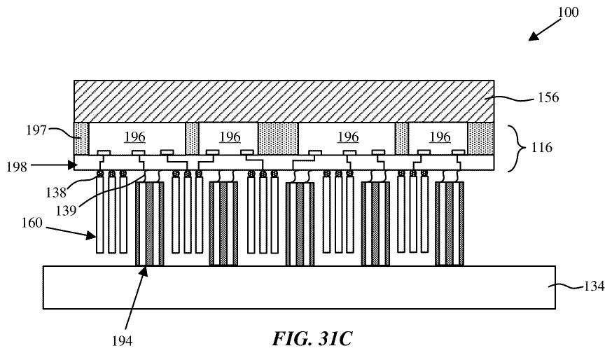

Referring now to FIG. 31A a schematic top layout view illustration is provided for a wafer 190 area supporting an array of compute 119 regions and memory die stacks 160 and PDN bridges 194 from which a plurality of integrated processors 116 can be scribed. FIG. 31A is substantially similar to that illustrated in FIG. 30A with the addition of PDN bridges 194 that can interspersed along with the memory die stacks 160.

FIG. 31B is a schematic cross-sectional side view illustration of a memory system including a processor 116 with surface mounted memory die stacks 160 and PDN bridges 194 in accordance with an embodiment. The integrated processor 116 with memory die stacks 160 and PDN bridges 194 can be mounted faced down onto a routing substrate 134 (e.g., with solder bumps, sockets, hybrid bonding, etc.) where there PDN bridges 194 provide clearance for the memory die stacks 160. The memory die stacks 160 and PDN bridges 194 may be mounted on the processor 116 with micro bumps 138, sockets, or hybrid bonding. The PDN bridges may be attached to the routing substrate using mechanically compliant connections 139 (e.g., sockets) such that both the PDN and mechanical needs are adequately met. A thermal solution 156 (e.g., lid, heat spreader) can optionally be bonded to the back side of the processor 116.

While the embodiment shown in FIG. 31B is illustrated as being fabricated from wafer-scale, such as complementary metal-oxide semiconductor (CMOS) wafer, embodiments are not so limited and embodiments can also be fabricated from reconstituted substrates, which can be wafer-scale. FIG. 31C is a schematic cross-sectional side view illustration of a memory system similar to that illustrated in FIG. 31B except the processor 116 is instead diced from a reconstituted substrate (organic using a redistribution layer, or organic using hybrid bonding methods) including a plurality of chiplets 196 embedded in a gap fill material 197 (e.g., molding compound, or an inorganic gap fill for hybrid bonding method, etc.) and connected with a redistribution layer (RDL) 198 which may include fanout wiring. In accordance with embodiments, the processor 116 may include a single chiplet 196 (or die), or include a plurality of chiplets 196, that may include different intellectual property (IP) blocks and/or be fabricated at different process nodes (e.g., transistor channel width, metal stacks, etc.).

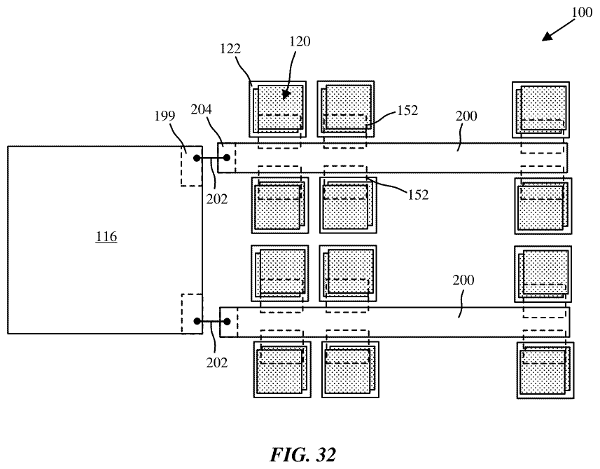

FIG. 32 is a schematic top layout view illustration of a scalable memory system with communication bars 200 in accordance with an embodiment. As shown, the processor 116 can include PHY 199 regions, connected to communication bar(s) 200 PHY 204 regions with routing 202. PHY 199 region and PHY 204 region may be die-to-die or SerDes regions for example. Additional circuitry can be offloaded into the communication bars 200, which communicate to memory die stacks 122 and corresponding buffer dies 122 through local interconnects 152, which may be passive (although may be active if required). Thus, PHY 199 region and PHY 204 region can customized die-to-die logic for example, allowing reduced routing 202 length. Other PHY circuitry such as buffering circuitry, optionally SerDes circuitry and network logic can be provided within the communication bar(s).

In utilizing the various aspects of the embodiments, it would become apparent to one skilled in the art that combinations or variations of the above embodiments are possible for forming a memory system with network routing for connecting multiple memory die stacks. Although the embodiments have been described in language specific to structural features and/or methodological acts, it is to be understood that the appended claims are not necessarily limited to the specific features or acts described. The specific features and acts disclosed are instead to be understood as embodiments of the claims useful for illustration.

What is claimed is:

1. A memory system comprising:
a routing substrate;
a processor on a first side of the routing substrate;
a buffer base die on the first side of the routing substrate;
a first memory die stack on the buffer base die; and
a second memory die stack on the buffer base die;
wherein the buffer base die includes network routing connected to both the first memory die stack and the second memory die stack.

2. The memory system of claim 1, wherein the buffer base die includes network routing circuitry to transmit a signal between the processor and the first memory die stack or the second memory die stack through the network routing.

3. The memory system of claim 2, wherein the network routing circuitry is to transmit the signal between the processor and both the first memory die stack and the second memory die stack through the network routing.

4. The memory system of claim 2, wherein the buffer base die includes buffering circuitry, serialization/deserialization (SerDes) circuitry, memory control circuitry, error correction circuitry, and test circuitry.

5. The memory system of claim 2, wherein the first memory die stack is laterally between the second memory die stack and a first edge of the processor.

6. The memory system of claim 5, further comprising:
a second buffer base die on the first side of the routing substrate;
a third memory die stack on the second buffer base die;
a fourth memory die stack on the second buffer base die;
wherein the second buffer base die includes second network routing connected to both the third memory die stack and the fourth memory die stack; and
wherein the third memory die stack is laterally between the fourth memory die stack and the first edge of the processor.

7. The memory system of claim 2, wherein the first memory die stack and the second memory die stack are arranged side-by-side adjacent to a first edge of the processor.

8. The memory system of claim 7, further comprising:
a third memory die stack on the buffer base die;
a fourth memory die stack on the buffer base die;
wherein the network routing is additionally connected to the third memory die stack and the fourth memory die stack; and
wherein the first memory die stack is laterally between the third memory die stack and the first edge of the processor, and the second memory die stack is laterally between the fourth memory die stack and the first edge of the processor.

9. The memory system of claim 2, wherein the buffer base die is hybrid bonded with the routing substrate.

10. The memory system of claim 1, further comprising a local interconnect supporting die-to-die routing between the processor and the buffer base die, wherein the buffer base die includes equalizer logic.

11. The memory system of claim 1, further comprising a dummy memory die stack mounted on the buffer base die.

12. The memory system of claim 1, further comprising a flexible routing substrate mounted on the buffer base die, wherein the first memory die stack is mounted on the flexible routing substrate.

13. The memory system of claim 1, wherein the first memory die stack is mounted on a first area of the buffer base die, the first area of the buffer base die includes a die-to-die PHY region and a separate SerDes PHY region.

14. The memory system of claim 1, wherein the second memory die stack is a different type of memory die stack than the first memory die stack.

15. The memory system of claim 1, further comprising an optical engine mounted on the buffer base die.

16. A memory system comprising:
a processor; and
a memory die stack operably connected with the processor, wherein the memory die stack includes a bonding surface and a plurality of memory dies oriented orthogonal to the bonding surface.

17. The memory system of claim 16, wherein the processor is mounted on a first side of a routing substrate, and the bonding surface of the memory die stack is mounted on the first side of the routing substrate.

18. The memory system of claim 16, wherein the plurality of memory dies includes a plurality of through silicon vias (TSVs) parallel with the bonding surface.

19. The memory system of claim 16, wherein the plurality of memory dies is arranged in a first group of first memory dies and a second group of second memory dies, wherein the first memory dies are thicker than the second group of memory dies.

20. The memory system of claim 16, further comprising one or more thermal shim layers laterally between adjacent memory dies in the plurality of memory dies.

21. The memory system of claim 16, further comprising a buffer base die, wherein the memory die stack is mounted on a top side of the buffer base die.

22. The memory system of claim 21, further comprising a plurality of memory die stacks mounted on the top side of the buffer base die.

23. The memory system of claim 22, wherein the buffer base die includes network routing circuitry to transmit a signal between the processor and a first memory die stack or a second memory die stack of the plurality of memory die stacks through the network routing.

24. The memory system of claim 23, wherein the network routing circuitry is to transmit the signal between the processor both the first memory die stack and the second memory die stack through the network routing.

25. A memory system,
a processor; and
a plurality of memory die stacks mounted on the processor.

26. The memory system of claim 25, wherein each memory die stack of the plurality of memory die stack includes a group of memory dies, each memory die orthogonally oriented orthogonal to the processor.

27. The memory system of claim 26, further comprising a plurality of power delivery network (PDN) bridges bonded to the processor.

28. The memory system of claim 25, wherein the processor is a single chip, and the plurality of memory die stacks is mounted on the single chip.

29. The memory system of claim 26, wherein the processor comprises a plurality of chiplets and a redistribution layer (RDL) spanning over the plurality of chiplets, and the plurality of memory die stacks is mounted on the RDL.
